(19) United States
(12) Patent Application Publication
(10) Pub. No.: US 2008/0041446 A1
(43) Pub. Date: Feb. 21, 2008

(54) DYE-SENSITIZED SOLAR CELLS AND METHOD FOR FABRICATING SAME

(75) Inventors: Jyh-Ming Wu, Hsinchu County (TW); Cheng-Che Yang, Taipei City (TW); Song-Yeu Tsai, Taipei City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/561,371

(22) Filed: Nov. 17, 2006

(30) Foreign Application Priority Data
Aug. 9, 2006 (TW) TW95129162

(51) Int. Cl. H01L 31/00

(52) U.S. Cl. 136/263

(57) ABSTRACT

A dye-sensitized solar cell (DSSC) comprising nanoparticles formed on a surface of a nanowire formed on a substrate and a method of fabricating the same is disclosed. The dye-sensitized solar cell comprises a first substrate. A nanowire is formed on the first substrate. A plurality of nanoparticles is then contacted with a surface of the nanowire. The dye-sensitized solar cell further comprises a dye adsorbed onto a surface of the nanoparticles. A second substrate is corresponded to the first substrate. Finally, an electrolyte is filled between the first substrate and the second substrate, and in contact with the dye and nanoparticles. The nanoparticles are bonded to the surface of nanowire to extend and increase surface contact with the dye for promoting cell efficiency (η) of the dye-sensitized solar cell.

### BACKGROUND OF THE INVENTION

1. Field of the Invention

The present invention relates to dye-sensitized solar cells and a method for fabricating same and more particularly to a dye-sensitized solar cell comprising nanoparticles formed on a surface of a nanowire and a method for fabricating same.

2. Description of the Related Art

Low or non-polluting power sources have become a subject of great interest due to global warming, the increasing scarcity of raw materials, environmental conditions and other concerns. Solar cells, which capture solar energy, are a popular alternative as they emit relatively little or no pollution, and have a long productive life.

Conventional solar cells can be divided into. Semiconductor solar cells, such as photovoltaic, and photo electrochemical solar cells, such as, dye-sensitized solar cells (DSSC). FIG. 1A shows a cross section of conventional dye-sensitized solar cells. A plurality of nanoparticles 14 is formed on a substrate 10. A dye 18 is then formed on the substrate 10 and in contact with nanoparticles 14. The nanoparticles 14 are arranged randomly, so that the nanoparticles 14 become a thin film. While a surface area of the nanopartitcles 14 is increasing, the thin film is densified, thus, the surface in contact with dye 18 is reduced. The recombination effect of electrons, for example electrons captured by positive charge of nanoparticles, is generated since defects of the densified nanoparticles, dye 18 thus does not effectively function, resulting in exciting and passing electrons to the conductive band of nanoparticles 14. Accordingly, cell efficiency (η) of the dye-sensitized solar cell suffers.

In FIG. 1B, a dye-sensitized solar cell comprising nanowires, as disclosed in patent cooperation treaty publication number WO2005/017957, is depicted. A nanowire 15 is formed on a substrate 10. Dye 18 is then adsorbed on a surface of the nanowire 15. While the nanowire 15 is a formation of single crystal, the nanowire 15 has a specific growth direction. And after thermal process, active bond on the surface of the nanowire 15 is not enough to form chemical bonding to dye 18, result in adsorption efficiency between the dye 18 and nanowire 15 is decrease. The contacting surface between nanowire 15 and dye 18 is decrease, since the dye 18 does not effective adsorb on the surface of the nanowire 15. So that, cell efficiency of the dye-sensitized solar cell does not effectively promote.

A dye-sensitized solar cell comprising an increased surface contacted with dye is needed to promote cell efficiency.

### BRIEF SUMMARY OF INVENTION

Accordingly, an object of the invention is to provide a method of fabricating a dye-sensitized solar cell. The method includes providing a first substrate and forming a nanowire thereon. A plurality of nanoparticles is formed on the surface of the nanowire. The method further includes providing a dye on the first substrate and contacting with the nanoparticles. A second substrate is then provided and corresponding to the first substrate. An electrolyte is filled between the first substrate and the second substrate, wherein the electrolyte contacts the nanowire and the nanoparticles. The nanoparticles are linearly arranged on the surface of the nanowire. The nanowire has a large surface area, high volume ratio, and aspect ratio. A surface contacted with the dye is increasing, while nanoparticles formed on the surface of the nanowire. According that, the cell efficiency of the dye-sensitized solar cell is promoted.

Another object of the invention is to provide a dye-sensitized solar cell. The dye-sensitized solar cell comprises a first substrate. A nanowire is formed on the first substrate, and a plurality of nanoparticles is then in contact with a surface of the nanowire. The dye-sensitized solar cell further comprises a dye adsorbed on a surface of the nanoparticles, a second substrate corresponding to the first substrate. An electrolyte is between the first substrate and the second substrate and in contact with the nanoparticles and the dye. The nanowire has a large surface area, high volume ratio, and aspect ratio. A surface contacted with the dye is increasing, while nanoparticles formed on the surface of the nanowire. According that, the cell efficiency of the dye-sensitized solar cell is promoted.

A detailed description is given in the following embodiments with reference to the accompanying drawings.

### BRIEF DESCRIPTION OF DRAWINGS

The present invention can be more fully understood by reading the subsequent detailed description and examples with references made to the accompanying drawings, wherein:

FIG. 1A to 1B show cross-sections of conductive substrate of a conventional dye-sensitized solar cell;

FIG. 2A to 2F show cross-sections of fabricating a dye-sensitized solar cell according to the embodiment of the invention;

FIG. 3 shows a cross-section of a dye-sensitized solar cell according to the embodiment of the invention;

FIG. 4A to 4D show graphs of current density vs. bias voltage of dye-sensitized solar cell comprising different arrangement of nanoparticles formed on the surface of the nanowire; and

FIG. 5 shows a flow chart of fabricating a dye-sensitized solar cell according to the embodiment of the invention.

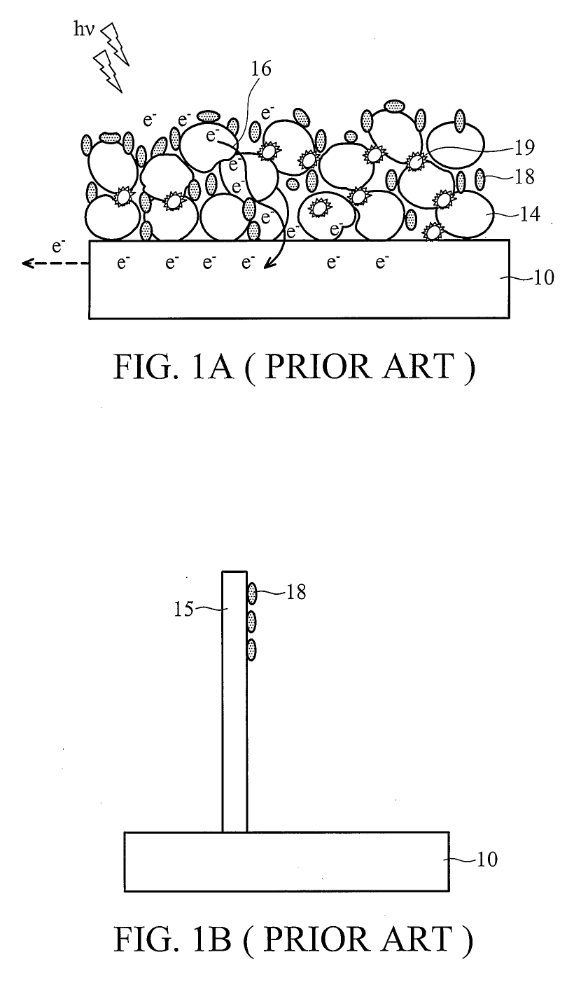

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

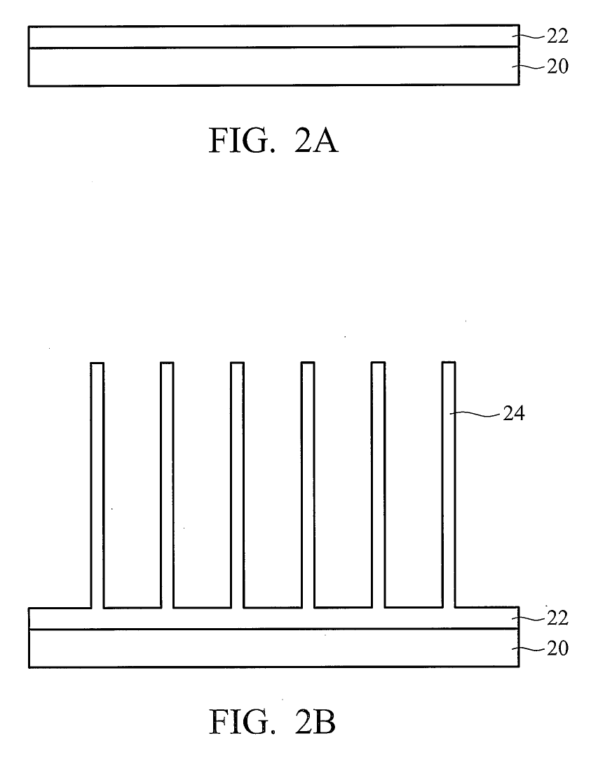

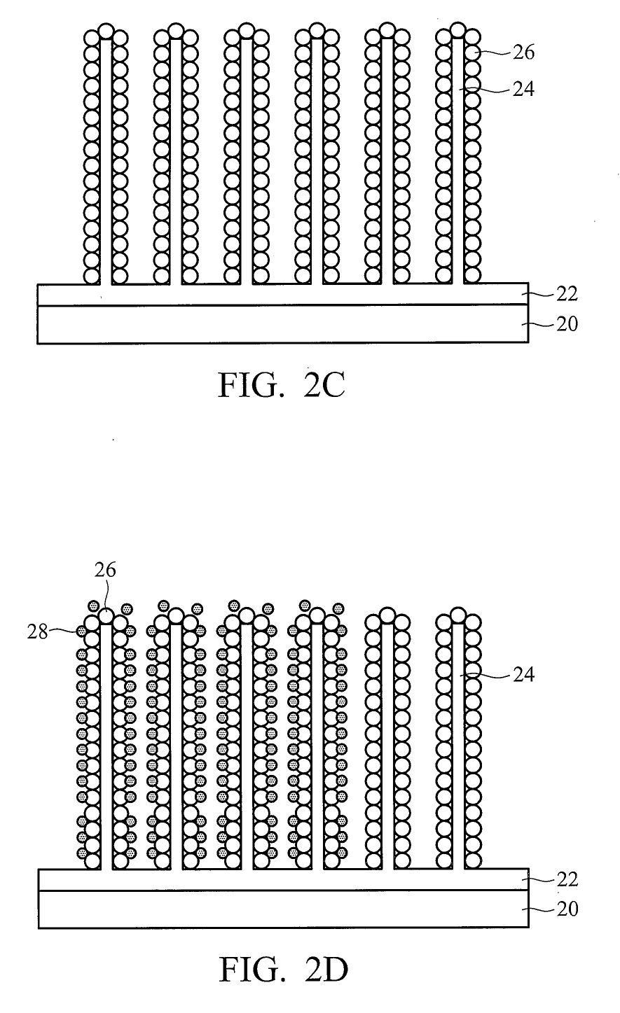

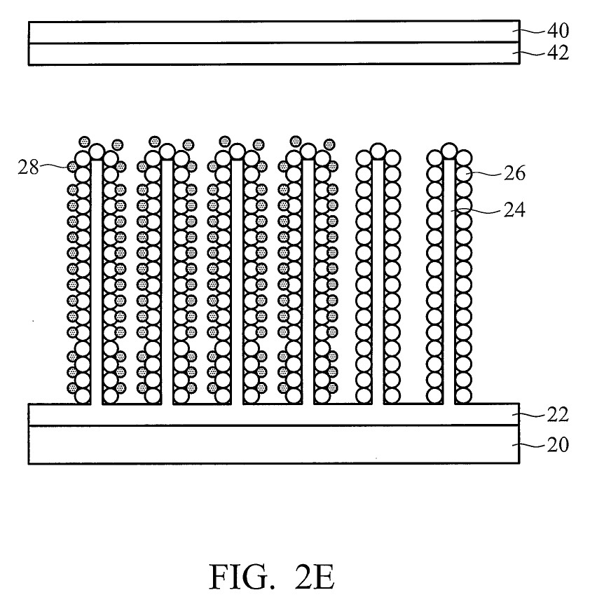

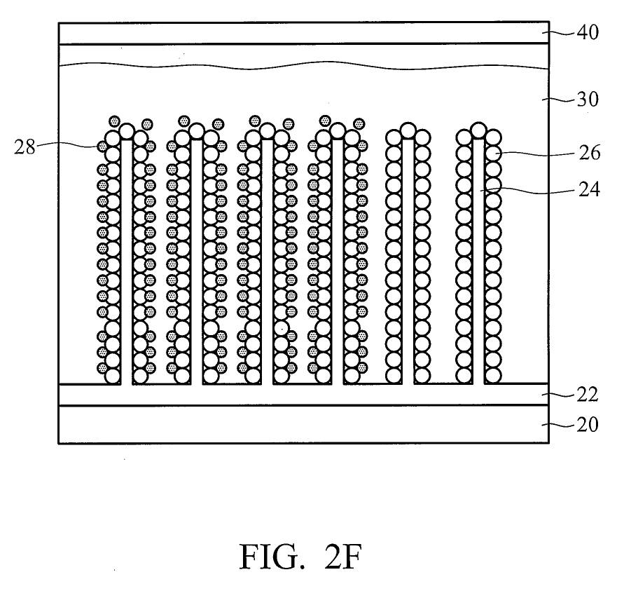

Referring to FIG. 2A, a first substrate 20 is provided. The first substrate 20 may comprises any suitable material. For example the material may be rigid, flexible, transparent, semitransparent, metal or semiconductor comprising silicon or gallium arsenide. Preferably, the first substrate 20 may be glass or polymer comprising plastic.

In FIG. 2A, a conductive layer 22 is formed on the first substrate 20 to provide a path for electron flow. As shown in FIG. 2B, a nanowire 24 is formed over the first substrate 20 to increase a contact surface conductive layer 22 and subsequent dye. The nanowire 24 may also be referred to as a nanorod. Preferably, the nanowire 24 and conductive layer 22 are formed by an in situ process, for example thermal evaporation, sputtering or applicable process well-known in the art. The conductive layer 22 and the nanowire 24 are preferably, for example, indium tin oxide (ITO), aluminum doped zinc oxide (AZO), antimony doped tin dioxide (ATO), fluorine doped tin dioxide (FTO), conductive impurity doped titanium oxide (TiO₂) or other semiconductor oxide having a preferable matching potential with the dye.

The nanowire 24 is conductive and combines with the conductive layer 22 to increase the contact surface between the conductive layer 22, and the nanowire 24 with the dye, and to provide a varied path for flow of electricity.

Preferably, the conductive layer 22 of indium tin oxide, for example, is formed on the first substrate 20, and then stacked and saturated in a vapor of indium tin oxide by thermal evaporation to form the nanowire 24. The conductive layer 22 and the nanowire 24 are formed at a temperature between 400° C. and 950° C., for 5 mins to 60 mins. A length of the nanowire 24 may be hundreds of micrometers, for example between 5 μm to 500 μm, and the nanowire 24 has a preferable diameter between 5 nm and 60 nm. Note that the conductive layer 22 are formed to provide electric flow path and to facilitate formation of the subsequent nanowire 24. Therefore, a thickness of the conductive layer 22 is adequate to fulfill the described purposes.

As shown in FIG. 2C, a plurality of nanoparticles 26 is formed on a surface of the nanowire 24, to increase surface contact with the subsequently formed dye. Preferably, a metal oxide layer is formed on the first substrate 20 (not shown) by, for example, dip coating or sputtering. The metal oxide layer is preferably titanium dioxide (TiO₂), zinc oxide (ZnO), silicon dioxide (SiO₂) or stannum dioxide (SnO₂). The metal oxide is then sintered at preferable temperature between 400° C. and 550° C. for 30 mins to 60 mins, to form the nanoparticles 26 on the surface of the nanowire 24. Preferably, the nanoparticles 26 have a diameter between 5 nm and 20 nm.

The preparation of the metal oxide may be Sol-Gel method. In one embodiment, a precursor comprising titanium alkoxides or titanium slats is provided. The precursor is processed by hydrolysis and condensation to form a nano titanium dioxide.

Preferably, the nanoparticles 26 are linearly or randomly arranged, and combined to the surface of the nanowire 24 for increasing the surface contact with subsequently formed dye. Note that the subsequent dye may be adsorbed on the surface of the nanowire 24 and between the nanoparticles 26 arranged in random. The nanoparticles 26 are formed on the surface of the nanowire 24 by chemical bond.

In FIG. 2D, a dye 28, also referred to as dye-sensitized dye, is provided on the first substrate 20 and adsorbed on the surface of the nanoparticles 26 to transform form solar energy to electric energy. In some embodiments, the dye 28 may be an organic metal complex dye comprising porphyrin or Ru-bipyridine (N3), or an organic dye comprising counmarin, indoline, cyanine, or rhodamine B. In some embodiments, the dye 28 is formed on the first substrate 20 by, for example, spin coating, and dip coating or filing recycle. Note that the dye 28 used is related to the material of nanoparticles 26, such as the adsorbability or oxidation reduction potential between the dye 28 and nanoparticles 26. Thus, the material of the dye 28 is an example for description of the embodiment, but is not limited to this.

Preferably, dye 28 adsorbed on the surface of the nanoparticles 26 by dipping nanoparticles 26 formed on the first substrate 20 to a dye solution between 0.2 mM and 1 mM for 18 hrs to 24 hrs.

Referring to FIG. 2E, a second substrate 40 comprising a conductive layer 42 is provided, and correspondingly to the first substrate 20. The conductive layer 42 is formed on the second substrate 40 by evaporation, sputtering, electroplating, deposition, or applicable process well-known in the art. The material of the second substrate 40 is the same as previously described. The conductive layer 42 may be metal comprising copper, platinum or silver, or any conductive material.

In FIG. 2F, an electrolyte 30 is filled between the first substrate 20 and the second substrate 40, to provide electron to dye 28 for reduction of dye 28. Preferably, the electrolyte 30 may be a solution comprising iodine ion and iodine complex.

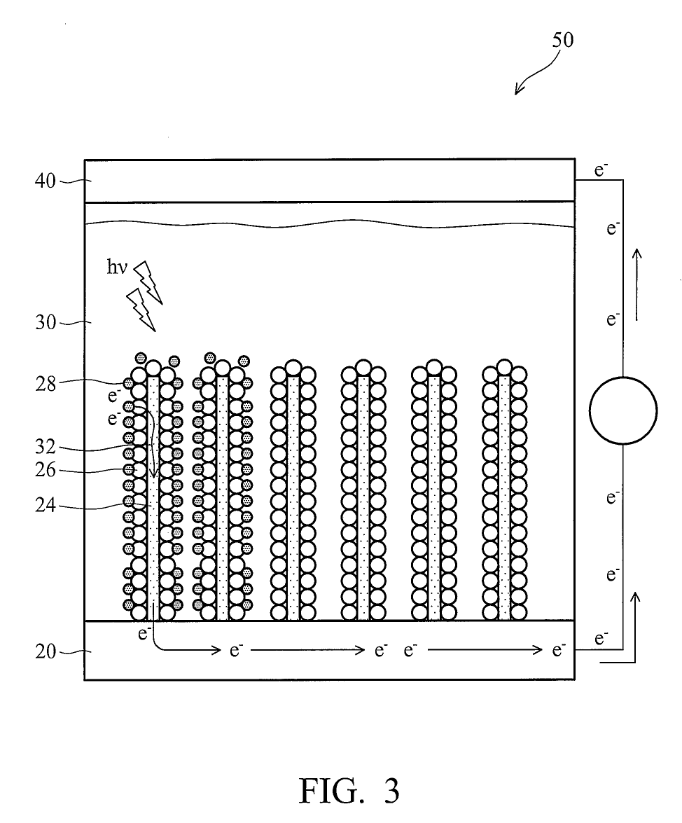

FIG. 3 shows a dye-sensitized solar cell 50 according to an embodiment of the invention. The dye 28 becomes excited and passes electrons to nanoparticles 26, while dye 28 absorbs solar energy. As shown, an electric flow path 32 in FIG. 3, electrons along the nanoparticles 26 pass through nanowire 24, the first substrate 20 (also called lower electrode) to the second substrate 40 (also called upper electrode) to generate current. Thereafter, electrons from electrolyte 30 are provided to dye 28 for reduction of oxidized dye 28. The above oxidization and reduction of dye 28 is repeatedly performed to generate current continually.

Note that the electron may pass to the first substrate 20 by adjacent nanoparticles 26.

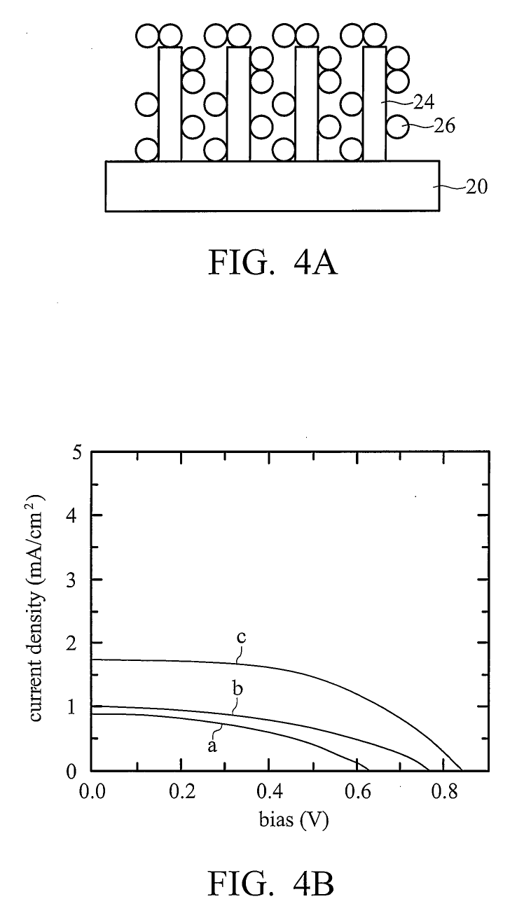

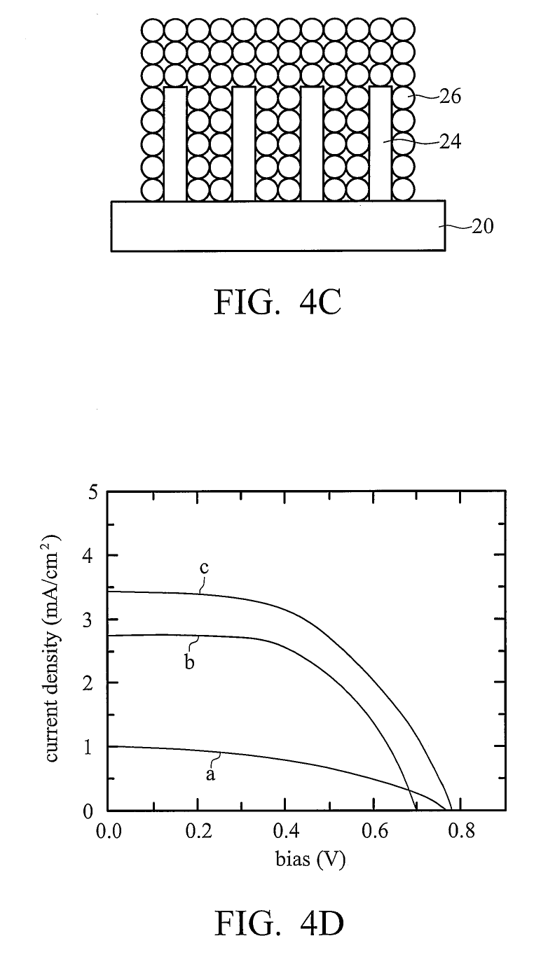

FIG. 4A shows a dye-sensitized solar cell according to another embodiment of the invention. A plurality of nanoparticles 26 is formed a surface of a nanowire 24, and arranged in random. The arrangement may be, for example, nanoparticles 26 separated by a distance by dye 28, or in contact with each other.

Thereafter, FIG. 4B shows a graph of current density (mA cm⁻²) vs. bias voltage (V) according to the dye-sensitized solar cell in 4A. Curve a depicts a dye-sensitized solar cell comprising the nanoparticles. Curve b depicts a dye-sensitized solar cell comprising the nanowire. Curve c depicts a dye-sensitized solar cell comprising nanoparticles formed on the surface of the nanowire. It is found that curve c, namely a dye-sensitized solar cell comprising nanoparticles formed on the surface of the nanowire, shows the product of current multiplied voltage is higher than curves a and b. Cell efficiency (η) of dye-sensitized solar cell has a positive relative to the product of current and voltage. Accordingly, the dye-sensitized solar cell of the invention has greater cell efficiency the dye-sensitized solar cell comprising a single nanowire or nanoparticles.

FIG. 4C shows the nanoparticles 26 formed on the surface of the nanowire 24 of the first substrate 20 and arranged linearly. The arrangement may be, for example, the nanoparticles 26 contacting each other without a gap. In some embodiments, dye (not shown) may be adsorbed on the surface of the nanoparticles 26, or adjacent to nanoparticles 26.

FIG. 4D shows a graph of current density (mA cm⁻²) vs. bias voltage (V) according to dye-sensitized solar cell in FIG. 4C. Curve a depicts a dye-sensitized solar cell comprising nanoparticles. Curve b depicts a dye-sensitized solar cell comprising nanowire. Curve c depicts a dye-sensitized solar cell comprising nanoparticles formed on the surface of the nanowire. It is found that curve c, namely a dye-sensitized solar cell comprising nanoparticles formed on the surface of the nanowire, shows the product of current multiplied voltage is higher than curves a and b. Cell efficiency (η) of dye-sensitized solar cell has a positive relation relate to product of current and voltage. Accordingly, the dye-sensitized solar cell of the invention has better cell efficiency than the dye-sensitized solar cell comprising a single nanowire or nanoparticles.

It's found that the cell efficiency of the dye-sensitized solar cell comprising nanoparticles formed on the surface of the nanowire is greater than the dye-sensitized solar cell comprising a single nanowire or nanoparticles, in FIG. 4A to 4D. Comparing the arrangement of nanoparticles in FIG. 4A with 4B shows that the cell efficiency of the dye-sensitized solar cell comprising nanoparticles formed linearly on the surface of the nanowire is greater than the dye-sensitized solar cell comprising nanoparticles formed randomly on the surface of the nanowire.

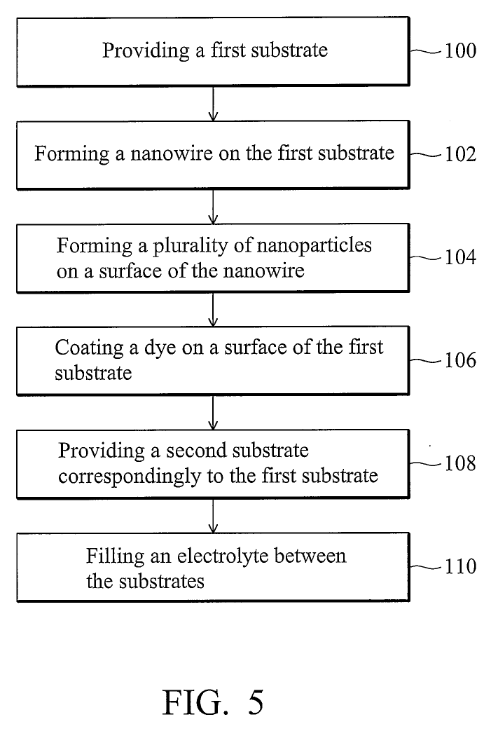

FIG. 5 shows a flow chart of fabricating a dye-sensitized solar cell according to an embodiment of the invention. A first substrate is provided, as step 100. A nanowire is then formed on the first substrate, as step 102. A conductive layer is formed on the first substrate, before the nanowire is formed. A plurality of nanoparticles is formed on the surface of the nanowire, as step 104. The nanoparticles may be arranged linearly and combined with the nanowire in chemical bond. A dye is then formed on the first substrate by dip coating, as step 106. Thereafter, a second substrate is provided and corresponding to the first substrate, as step 108. As shown in step 110, an electrolyte is filled between the substrates to yield a dye-sensitized solar cell.

A conductive substrate of the invention comprises a plurality of nanoparticles formed on a surface of a nanowire. A sheet resistance of the conductive substrate is measured by 4 point probe, wherein the sheet resistance is about 0.7 Ω/cm². A conventional conductive substrate, for example, FTO used in dye-sensitized solar cell has a sheet resistance between 5 Ω/cm² and 7 Ω/cm². Thus, the conductive substrate of the invention has better conductivity than the conventional. That is, while electrons pass from the dye to the conductive substrate, the conductive substrate of the invention has a lower resistance, cell efficiency is thus improved.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of fabricating a dye-sensitized solar cell, comprising:
providing a first substrate;
forming a nanowire on the first substrate; and
forming a plurality of nanoparticles on a surface of the nanowire.

2. The method of claim 1, further comprising forming a dye contacting the nanoparticles, on the first substrate.

3. The method of claim 2, further comprising:
providing a second substrate corresponding to the first substrate; and
filling an electrolyte contacting the dye and the nanoparticles, between the first substrate and the second substrate.

4. The method of claim 3, further comprising forming a conductive layer on the first substrate, before forming the nanowire.

5. The method of claim 3, wherein forming the nanowire comprises thermal evaporation or sputtering.

6. The method of claim 5, wherein forming the nanowire has a temperature of between 400° C. and 950° C.

7. The method of claim 6, wherein forming the nanowire has a process time of between 5 min and 60 min.

8. The method of claim 3, wherein forming the nanoparticles comprises:
forming a metal oxide layer on the first substrate; and
sintering the metal oxide layer.

9. The method of claim 8, wherein forming the metal oxide layer comprises dip coating or sputtering.

10. The method of claim 8, wherein the metal oxide layer is heated at a temperature of between 400° C. and 550° C.

11. The method of claim 3, wherein providing the dye on the first substrate comprises spin coating or dip coating.

12. The method of claim 3, wherein the nanoparticles arrange linearly and are combined with the surface of the nanowire.

13. A dye-sensitized solar cell, comprising:
a first substrate;
a nanowire formed on the first substrate; and
a plurality of nanoparticles contacted with a surface of the nanowire.

14. The dye-sensitized solar cell of claim 13, wherein the nanoparticles are arranged linearly.

15. The dye-sensitized solar cell of claim 13, further comprising a dye adsorbed on a surface of each nanoparticle.

16. The dye-sensitized solar cell of claim 15, further comprising:
a second substrate corresponding to the first substrate; and
an electrolyte filled between the first substrate and the second substrate and contacted with the dye and the nanoparticles.

17. The dye-sensitized solar cell of claim 16, wherein the first substrate and the second substrate comprise plastic or glass.

18. The dye-sensitized solar cell of claim 17, further comprising a conductive layer formed on corresponding surfaces of the first substrate and the second substrate.

19. The dye-sensitized solar cell of claim 16, wherein the nanowire comprises indium tin oxide, aluminum doped zinc oxide, antimony doped tin dioxide, fluorine doped tin dioxide, or titanium dioxide.

20. The dye-sensitized solar cell of claim 16, wherein the nanowire has a diameter in a range of about 5 nm and 60 nm.

21. The dye-sensitized solar cell of claim 16, wherein the nanowire has a length in range of about 5 μm and 500 μm.

22. The dye-sensitized solar cell of claim 16, wherein the nanoparticles comprise zinc dioxide, titanium dioxide, silicon dioxide or tin dioxide.

23. The dye-sensitized solar cell of claim 16, wherein each nanoparticle has a diameter in a range of about 5 nm to 20 nm.

24. The dye-sensitized solar cell of claim 16, wherein the dye comprises organic dye or organic metal complex.

25. The dye-sensitized solar cell of claim 16, wherein the electrolyte comprises iodine ion and iodine complex ion.
